(19) United States
(12) Patent Application Publication
(10) Pub. No.: US 2016/0343595 A1
(43) Pub. Date: Nov. 24, 2016

(54) CORROSION RESISTANT GAS DISTRIBUTION MANIFOLD WITH THERMALLY CONTROLLED FACEPLATE

(71) Applicant: Lam Research Corporation, Fremont, CA (US)

(72) Inventors: Gary Bridger Lind, Nevada City, CA (US); Panya Wongsenakhum, Santa Clara, CA (US); Eric H. Lenz, Livermore, CA (US)

(21) Appl. No.: 14/716,823

(22) Filed: May 19, 2015

(51) Int. Cl. H01L 21/67; C23C 16/46; C23C 16/455

(52) U.S. Cl. CPC H01L 21/67069; C23C 16/45544; C23C 16/46; C23C 16/463; C23C 16/45565

(57) ABSTRACT

An apparatus for semiconductor manufacturing is provided. The apparatus may include a gas distribution manifold. The gas distribution manifold may include a faceplate assembly having a backplate region, a faceplate region opposite the backplate region, and a first pattern of gas distribution holes. The gas distribution manifold may also include a temperature control assembly in thermally conductive contact with the face plate assembly. The temperature control assembly may include a cooling plate assembly, a heating plate assembly offset from the cooling plate assembly to form a gap, and a plurality of thermal chokes distributed within the gap.

### BACKGROUND

Semiconductor processing tools often include components designed to distribute process gases in a relatively uniform manner across a semiconductor substrate or wafer. Such components are commonly referred to in the industry as “showerheads.” Showerheads typically include a faceplate that fronts a semiconductor processing volume in which semiconductor substrates or wafers may be processed. The faceplate may include a plurality of through-holes that allow gas in the plenum volume to flow through the faceplate and into a reaction space between the substrate and the faceplate (or between a wafer support supporting the wafer and the faceplate). The through-holes are typically arranged such that the gas distribution across the wafer results in substantially uniform substrate processing.

### SUMMARY

Among various implementations disclosed herein is an apparatus for semiconductor manufacturing. The apparatus may include a gas distribution manifold. The gas distribution manifold may include a faceplate assembly. The faceplate assembly may have a backplate region at least partially bounded by a first interior surface and a first exterior surface. The faceplate assembly may also have a faceplate region opposite the backplate region. The faceplate region may be at least partially bounded by a second interior surface and a second exterior surface. The faceplate assembly may also have a first pattern of gas distribution holes. The gas distribution holes may be distributed across the second interior surface and each gas distribution hole may span between the second exterior surface and the second interior surface. The gas distribution manifold may also include a temperature control assembly in thermally conductive contact with the second exterior surface. The temperature control assembly may have a cooling plate assembly having one or more cooling passages configured to be connected with a cooling source. The temperature control assembly may also have a heating plate assembly offset from the cooling plate assembly to form a gap. The temperature control assembly may also have a plurality of thermal chokes distributed within the gap. The thermal chokes may be configured to thermally choke heat flow between the heating plate assembly and the cooling plate assembly.

In some implementations, the thermal chokes may have a total cross-sectional area in a plane parallel to the second exterior surface that is between 1.7% and 8.0% of the surface area of the first exterior surface. The thermal chokes may be arranged in one or more circular patterns and may be evenly spaced within each of the one or more circular patterns.

Also or alternatively, the thermal chokes may include a spacer having a polygonal or circular cross-sectional shape in a plane parallel to the second exterior surface. The spacers may be integral with the heating plate or the cooling plate. The spacers may be annular in the plane parallel to the second exterior surface. Each spacer may include a center region, and each thermal choke may include a bolt that passes through the center region.

In some implementations, the faceplate assembly may be composed primarily of a ceramic material. The faceplate assembly may also include a ceramic inlet. Process gases flowed into the gas distribution manifold via the ceramic inlet may be exposed primarily to the ceramic material of which the faceplate assembly is composed when within the gas distribution manifold.

In some implementations, the faceplate assembly may include a plenum region at least partially bounded by the first and second interior surfaces and that may include a network of gas distribution passages for distributing gas. The gas distribution passages may have a first total cross-sectional area in a plane nominally parallel to the faceplate assembly. The plenum region may also include a plurality of interstitial regions defined by the network of gas distribution passages. The interstitial regions may span between the first interior surface and the second interior surface. The interstitial regions may have a second total cross-sectional area in the plane nominally parallel to the faceplate assembly. The second total cross-sectional area may be between 30% and 40% of a sum of the first cross-sectional area and the second cross-sectional area. The interstitial regions may be free of gas distribution holes. Each interstitial region may form a thermally conductive pathway between the faceplate region and the backplate region.

In some implementations, the gas distribution passages may include a plurality of radial spoke passages, and a plurality of concentric annular passages fluidically connected with the plurality of radial spoke passages. The radial spoke passages may form a circular array about an inlet of the gas distribution manifold. Each radial spoke passage may have at least a portion where that radial spoke passage decreases in cross-sectional area in a plane perpendicular to the radial spoke passage as a function of increasing distance from the inlet.

In some implementations, the second exterior surface may include a circumferential wall portion that is offset in a direction away from the second interior surface from a center portion of the second exterior surface enclosed within the circumferential wall portion. The circumferential wall portion may be configured to interface with a wafer support pedestal located in a semiconductor processing chamber when the gas distribution manifold is installed in the semiconductor processing chamber so as to define a microvolume bounded, at least in part, by the center portion, the circumferential wall portion, and a wafer support surface of the wafer support pedestal when the apparatus is used to perform one or more semiconductor processing operations on a wafer.

In some implementations, the apparatus may also include a vacuum manifold configured to remove process gases from the microvolume. The vacuum manifold may be located between the heating plate assembly and the faceplate assembly. The faceplate assembly may include exhaust ports in fluidic communication with the vacuum manifold. The vacuum manifold may include flow passages configured to provide asymmetric flow paths to gases flowing within the vacuum manifold.

In some implementations, the apparatus may also include an outer passage. The outer passage may be configured to provide a barrier gas to a seal zone between the second exterior surface and the wafer support pedestal. The seal zone may be a region where the second exterior surface and the wafer support pedestal are closest when the microvolume exists.

In some implementations, the faceplate assembly may include a thermocouple configured to measure a temperature of the faceplate region.

These and other features will be described in more detail below with reference to the drawings.

### BRIEF DESCRIPTION OF THE DRAWINGS

FIG. 1 shows a cross-sectional view of an example of an apparatus for semiconductor manufacturing, in accordance with some implementations.

FIG. 2 shows an isometric section view of a gas distribution manifold of the example apparatus of FIG. 1, in accordance with some implementations.

FIG. 3 shows a cross-sectional view of an example faceplate assembly of the example gas distribution manifold of FIG. 2, in accordance with some implementations.

FIG. 4 shows an isometric bottom view of a faceplate region of the example faceplate assembly of FIG. 3, in accordance with some implementations.

FIG. 5 shows an isometric view of a plenum region of the example faceplate assembly of FIG. 3, in accordance with some implementations.

FIG. 6 shows a top view of the plenum region of the example faceplate assembly of FIG. 3, in accordance with some implementations.

FIG. 7 shows an isometric view of a backplate region of the example faceplate assembly of FIG. 3, in accordance with some implementations.

FIG. 8 shows an exploded view of the example gas distribution manifold of FIG. 2, in accordance with some implementations.

FIG. 9 shows a top view of an example of a vacuum manifold of the example gas distribution manifold of FIG. 2, in accordance with some implementations.

FIG. 10 shows a top view of an example of a heating plate assembly of the example gas distribution manifold of FIG. 2, in accordance with some implementations.

FIG. 11 shows a top view of an example of a cooling plate assembly of the example gas distribution manifold 106 of FIG. 2, in accordance with some implementations.

FIG. 12 shows an isometric cut-away view of the example gas distribution manifold of FIG. 2 , in accordance with some implementations.

### DETAILED DESCRIPTION

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. In addition to semiconductor wafers, other work pieces that may take advantage of this invention include various articles such as printed circuit boards, magnetic recording media, magnetic recording sensors, mirrors, optical elements, micro-mechanical devices and the like.

Several conventions may have been adopted in some of the drawings and discussions in this disclosure. For example, reference is made at various points to “volumes,” e.g., “plenum volumes.” These volumes may be generally indicated in various Figures, but it is understood that the Figures and the accompanying numerical identifiers represent an approximation of such volumes, and that the actual volumes may extend, for example, to various solid surfaces that bound the volumes. Various smaller volumes, e.g., gas inlets or other holes leading up to a boundary surface of a plenum volume, may be fluidly connected to those plenum volumes.

It is to be understood that the use of relative terms such as “above,” “on top,” “below,” “underneath,” etc. are to be understood to refer to spatial relationships of components with respect to the orientations of those components during normal use of a showerhead or with respect to the orientation of the drawings on the page.

Among various deposition techniques used in semiconductor processing, one particular deposition technique may include atomic layer deposition (ALD). ALD processes use surface-mediated deposition reactions to deposit films on a layer-by-layer basis. In one example ALD process, a substrate surface may be exposed to a gas phase distribution of a first film precursor (P1). Some molecules of P1 may form a condensed phase atop the substrate surface, including chemisorbed species and physisorbed molecules of P1. The reactor is then evacuated to remove gas phase and physisorbed P1 so that only chemisorbed species remain. A second film precursor (P2) may then be introduced to the reactor so that some molecules of P2 adsorb to the substrate surface. The reactor may again be evacuated, this time to remove unbound P2. Subsequently, energy provided to the substrate activates surface reactions between adsorbed molecules of P1 and P2, forming a film layer. Finally, the reactor is evacuated to remove reaction by-products and possibly unreacted P1 and P2, ending the ALD cycle. Additional ALD cycles may be included to build film thickness. Other ALD processes may include other or different steps.

Semiconductor fabrication often requires that process gases, such as deposition and etch gases, be flowed in a uniform or controlled manner over a semiconductor wafer or substrate undergoing processing. To that end, a “showerhead,” also referred to herein as a gas distribution manifold and sometimes also referred to as a gas distributor, may be used to distribute gases across the surface of a wafer.

A conventional gas distribution manifold may sometimes fail due to varying heat loads. By way of illustration, heat transfer to a gas distribution manifold may vary when process gases change during different recipe steps of semiconductor manufacturing or when a wafer support pedestal drops for wafer transfers. Unfortunately, some components of a conventional gas distribution manifold, such as a faceplate, may deteriorate when exposed to such varying heat loads.

By contrast, some gas distribution manifolds disclosed herein may include a temperature control assembly, which may be used to fine-tune the temperature of a faceplate. Additionally, the faceplate of such a gas distribution manifold may, in some implementations, include thermally conductive pathways between the front of the faceplate, which may face a hot wafer and/or hot wafer support pedestal, and the back of the faceplate. Such pathways may dissipate heat transferred to the faceplate by allowing the heat to flow to other parts of the gas distribution manifold, such as the temperature control assembly.

Conventional gas distribution manifolds may also have a number of deficiencies resulting from material incompatibilities. By way of example, during an ALD process, a chlorine-based process gas may be introduced into a process chamber by a gas distribution manifold. On the other hand, during a cleaning process, a highly reactive cleaning gas, such as atomic and/or diatomic fluorine, may be introduced into the process chamber by the gas distribution manifold. At the same time, some hardware used in semiconductor manufacturing may be incompatible with some gases, such as those described above. Consequently, some components of traditional semiconductor manufacturing apparatuses may deteriorate when exposed to some process gases.

The gas distribution manifolds disclosed herein may include a ceramic gas delivery path to ameliorate some of the incompatibilities outlined in the preceding paragraph. By way of example, both cleaning gases and process gases may be fed into a gas distribution manifold by way of a ceramic inlet assembly, which may be integrated with a ceramic faceplate assembly. A detailed description of some examples of such inlet assemblies may be found in commonly assigned U.S. patent application Ser. No. 14/566,523, titled INLET FOR EFFECTIVE MIXING AND PURGING, filed on Dec. 10, 2014, and hereby incorporated by reference in its entirety and for all purposes. As such, both cleaning gases and process gases which flow through the gas distribution manifold may be exposed primarily to ceramic surfaces, which are compatible with both fluorine-based cleaning gases and chlorine-based process gases.

One example of a gas distribution manifold in accordance with this disclosure is described below, although it will be appreciated that the concepts embodied in such an example gas distribution manifold may be applied to other gas distribution manifold designs or configurations as well, and the present disclosure is not to be limited to only the depicted example.

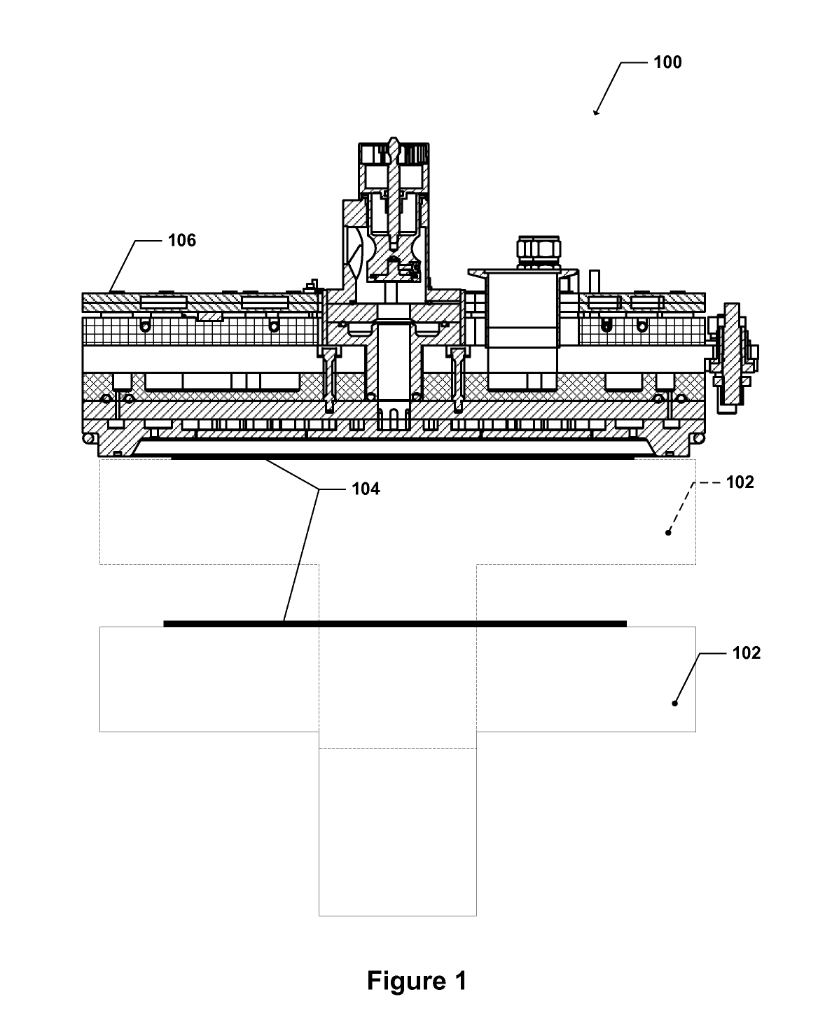

FIG. 1 shows a cross-sectional view of an example of an apparatus 100 for semiconductor manufacturing, in accordance with some implementations. Process gases may be flowed out of a gas distribution manifold 106 and distributed across a wafer 104; the wafer 104 may be supported by a wafer support pedestal 102 within a semi-conductor processing chamber 101 housing the gas distribution manifold 106. Distribution of the process gases across the wafer 104 may be accomplished through a pattern of gas distribution holes, described further below, which direct the flow of gas from inside the gas distribution manifold 106 to the wafer 104.

The position of the wafer support pedestal 102 may vary during different stages of semiconductor manufacturing. For example, the wafer support pedestal 102 may be in an elevated position (indicated in FIG. 1 by a dotted outline) when gases are being flowed over the wafer 104. On the other hand, the wafer support pedestal 102 may be in a dropped position (indicated in FIG. 1 by a solid outline) when the wafer 104 is being transferred.

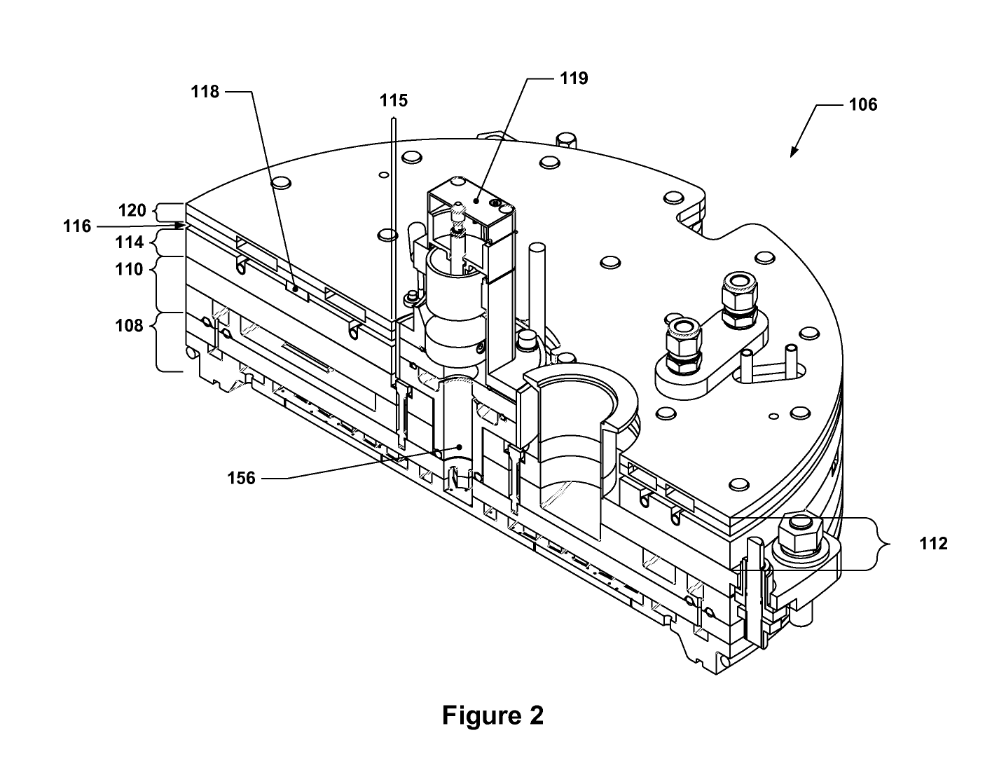

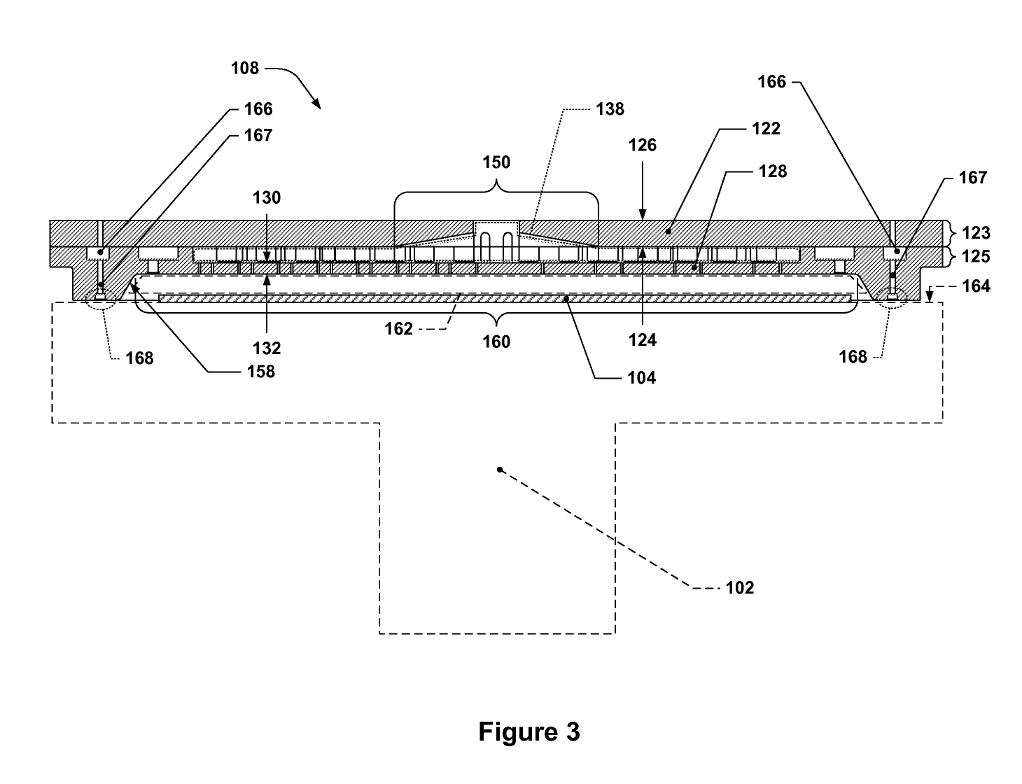

FIG. 2 shows an isometric section view of the gas distribution manifold 106 of FIG. 1, in accordance with some implementations. The gas distribution manifold 106 may contain a variety of components. For example, the gas distribution manifold 106 may include a faceplate assembly 108, which is described in further detail below in the context of FIGS. 3-7. The faceplate assembly 108 may be in thermally conductive contact with a temperature control assembly 112. The temperature control assembly 112 may include a cooling plate assembly 120, a heating plate assembly 114 offset from the cooling plate assembly 120 to form a gap 116, and a plurality of thermal chokes 118 distributed within the gap 116, each of which are described in further detail below.

Gas distribution manifolds typically include a plenum or plenum volume that is bounded, at least in part, by a faceplate with a plurality of gas distribution holes that lead to the outside of the gas distribution manifold. For example, FIG. 3 shows a cross-sectional view of an example of a faceplate assembly 108 of the gas distribution manifold 106 of FIG. 1, in accordance with some implementations.

The material composition of the faceplate assembly 108 may vary across implementations. For example, the faceplate assembly 108 may be composed primarily of a ceramic material such as alumina, aluminum nitride, or silicon carbide, etc. In other words, the overall structure of the faceplate assembly 108 may be made predominantly of the ceramic material, with the exception of small features such as threaded inserts, fittings, or other similar, small features that may difficult to manufacture from the ceramic material or that may need to be more resilient than the ceramic material. Similarly, when the term “primarily ceramic” is used to describe a flow path, such reference is to be understood to indicate that the surfaces that define the flow path are made from ceramic, with the exception of small portions of the flow path that are made from other materials, e.g., exposed surfaces of seals or o-rings, fittings, etc.

Along the same lines, the manner in which the faceplate assembly 108 is constructed may vary. For example, the faceplate assembly 108 may be formed by green-bonding two ceramic layers together. Green bonding, also referred to as co-sintering, generally describes a process where multiple pieces of un-sintered, also referred to as “green,” ceramic material are assembled and sintered together to form a single piece. For example, a layer 123 and a layer 125 may be green-bonded ceramic layers. Alternatively, the faceplate assembly 108 may be formed layer by layer using ceramic three dimensional (3D) printing, which may allow for the formation of the internal passages of the faceplate without bonding two ceramic layers together.

In some implementations, the gas distribution manifold 106 may include a primarily ceramic gas delivery path, which is compatible with both chlorine-based process gas and fluorine-based cleaning gas. By way of example, as discussed above, the faceplate assembly 108 may be constructed from a ceramic material. Similarly, process gas and cleaning gas may be fed into the faceplate assembly 108 through a ceramic inlet 156 that incorporates a cleaning gas inlet valve 119 with a ceramic sealing surface.

In some implementations, the cleaning gas inlet valve 119 may include a stainless steel bellows assembly, which is protected from deterioration. The cleaning gas inlet valve 119 may also effectively isolate cleaning gas generation hardware from chlorine-based process gases flowing through the gas distribution manifold 106 during the ALD process. For instance, the cleaning gas inlet valve 119 may include a piston assembly and a stainless steel bellows. The piston assembly may be designed to seal the bellows assembly from gases flowing through the cleaning gas inlet valve 119 when the cleaning gas inlet valve 119 is open. A detailed description of some examples of such cleaning gas inlet valves 119 may be found in commonly assigned provisional U.S. patent application 62/154,517, titled GAS INLET VALVE WITH INCOMPATIBLE MATERIALS ISOLATION, by Gary Bridger Lind and Panya Wongsenakhum, filed on Apr. 29, 2015, which is hereby incorporated by reference in its entirety and for all purposes.

Returning to FIG. 3, the faceplate assembly 108 may include a variety of regions. For example, the faceplate assembly 108 may include a backplate region 122 at least partially bounded by a first interior surface 124 and a first exterior surface 126. The faceplate assembly 108 may also include a faceplate region 128 opposite the backplate region 122. The faceplate region 128 may be at least partially bounded by a second interior surface 130 and a second exterior surface 132. Additionally, the faceplate assembly 108 may include a plenum region 138, which is at least partially bounded by the first interior surface 124 and the second interior surface 130.

In some implementations, the second exterior surface 132 may include a circumferential wall portion 158 that may be offset in a direction away from the second interior surface 130 from a center portion 160 of the second exterior surface 132 enclosed within the circumferential wall portion 158. The circumferential wall portion 158 may be configured to interface with the wafer support pedestal 102 when the gas distribution manifold 106 is installed in the semiconductor processing chamber and the wafer support is raised into the position shown so as to define a microvolume 162. The microvoluume 162 may be bounded, at least in part, by the center portion 160, the circumferential wall portion 158, and a wafer support surface 164 of the wafer support pedestal 102 when the apparatus is used to perform one or more semiconductor processing operations on a wafer. The microvolume 162 may effectively cease to exist when the wafer support 102 is lowered from the position shown.

As shown in FIG. 3, the faceplate assembly 108 may include an outer passage 166. The outer passage 166 may be an annular passage that may supply barrier gas to riser passages 167. Riser passages 167 may be configured to provide the barrier gas to a seal zone 168 between the second exterior surface 132 and the wafer support pedestal 102. As shown in FIG. 3, the seal zone may be a region where the second exterior surface 132 and the wafer support pedestal 102 are closest when the microvolume 162 exists, such that the gas distribution manifold 106 may provide barrier gas to the seal zone 168 by way of the outer passage 166 during semiconductor operations. As a result, a gas containment seal of around the microvolume 162 may be accomplished without direct contact between the faceplate assembly 108 and the wafer support pedestal 102. Alternatively, barrier gas may be provided to the seal zone 168 by way of gas distribution passages in the wafer support pedestal 102.

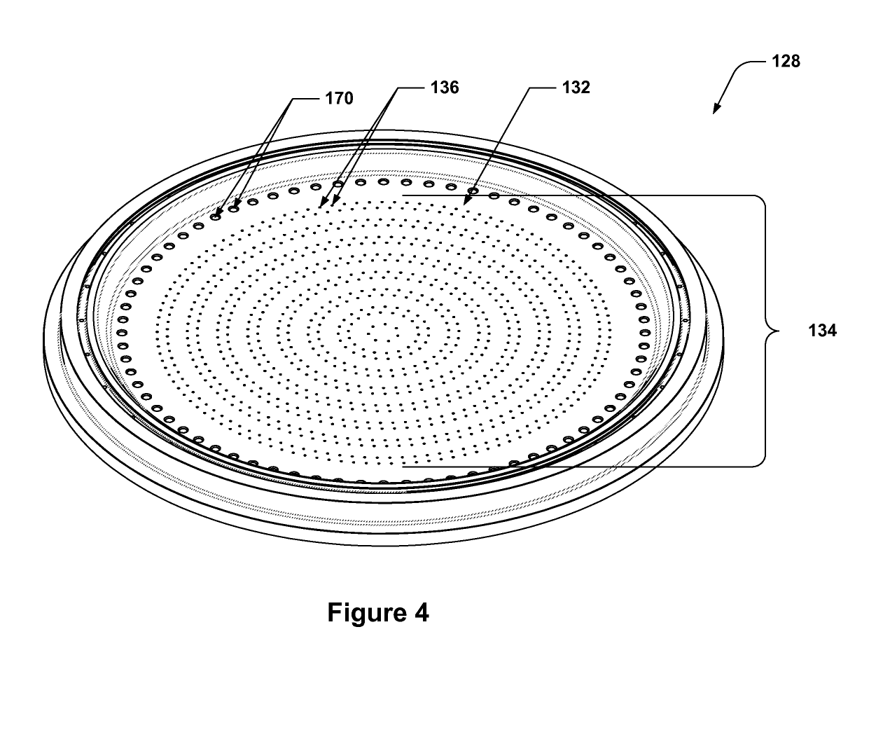

FIG. 4 shows an isometric bottom view of the faceplate region 128 of the faceplate assembly 108 of FIG. 3, in accordance with some implementations. The faceplate region 128 may include first pattern 134 of gas distribution holes 136. As shown in FIG. 4, the gas distribution holes 136 may be distributed across the second interior surface 130 of FIG. 3 and each gas distribution hole 136 may span between the second exterior surface 132 and the second interior surface 130. As described above, the gas distribution holes 136 may serve to flow gases over the wafer 104 of FIGS. 1 and 3. In some implementations, as shown, the gas distribution holes 136 may be distributed in a plurality of concentric radial or circular arrays.

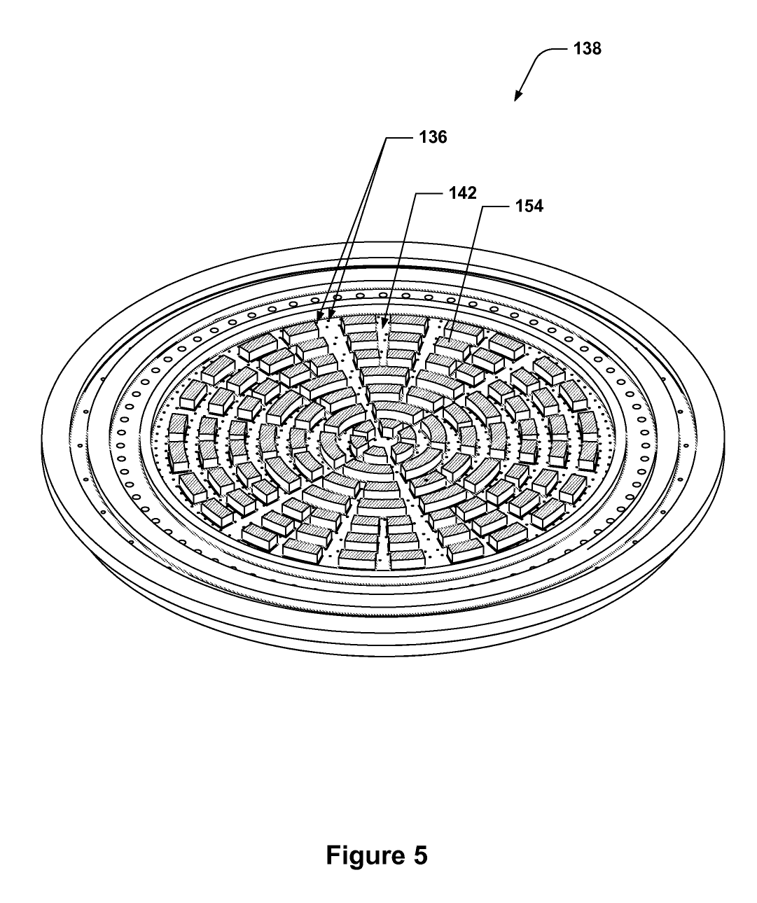

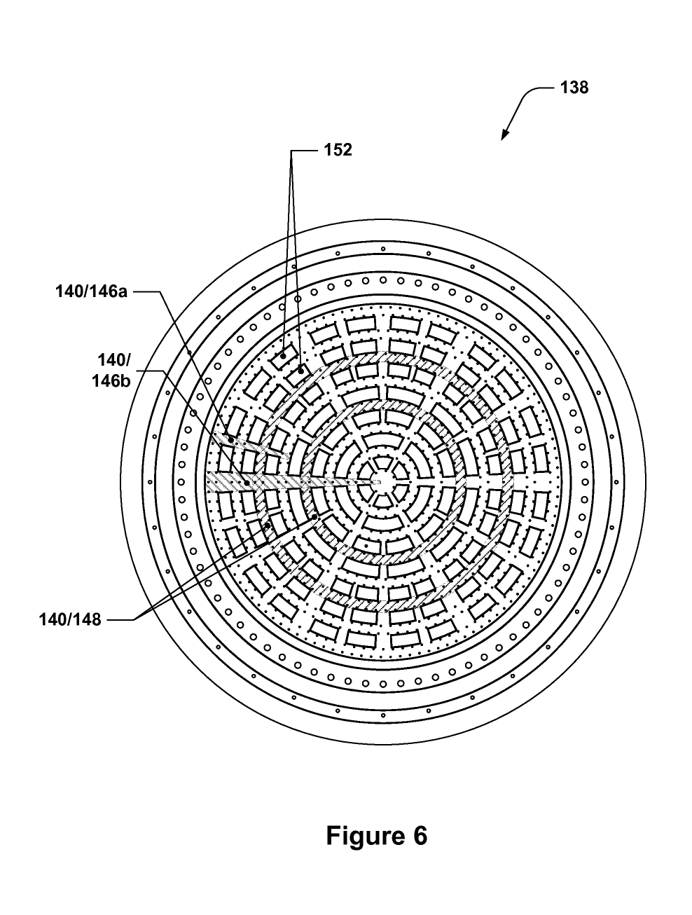

FIG. 5 shows an isometric view of the plenum region 138 of the faceplate assembly 108 of FIG. 3, in accordance with some implementations. FIG. 6 shows a top view of the plenum region 138 of FIG. 5, in accordance with some implementations.

As shown in FIG. 6, the plenum region 138 may include a network of gas distribution passages 140 for distributing gas. The gas distribution passages 140 may have a first total cross-sectional area 142 in a plane nominally parallel to the faceplate assembly 108, e.g., in a plane parallel to the wafer support surface 164 or the wafer 104, if it is present.

The gas distribution passages 140 may be positioned to optimize gas flow within the plenum region 138. For example, the gas distribution passages 140 may include a plurality of radial spoke passages 146 and a plurality of concentric annular passages 148 fluidically connected with the plurality of radial spoke passages 146. As shown in FIGS. 5 and 6 some of the radial spoke passages 146 (e.g. 146a) may have a shorter radial length than other radial spoke passages 146 (e.g. 146b). In some implementations, the gas distribution passages 140 may increase in height nearer to the inlet 156 to optimize gas flow within the plenum region 138. For example, in some implementations, the radial spoke passages 146 may form a circular array about the inlet 156 and each radial spoke passage 146 may have a portion 150 of FIG. 3 where that radial spoke passage 146 of FIGS. 5 and 6 decreases in cross-sectional area in a plane perpendicular to the direction along which the radial spoke passage 146 extends as a function of increasing distance from the inlet 156.

The plenum region 138 may also include a plurality of interstitial regions 152 located in the interstices defined by the network of gas distribution passages 140. As discussed above, the interstitial regions 152 may function to transfer heat from the faceplate region 128 to the backplate region 122. As such, the interstitial regions 152 may form a thermally conductive pathway between the faceplate region 128 and the backplate region 122. The interstitial regions 152 may by free of gas distribution holes and may span between the first interior surface 124 and the second interior surface 130.

Unlike conventional gas distribution manifolds, the interstitial regions 152 may provide a thermal pathway between the faceplate region 128 and the temperature control assembly 112 of FIG. 2. In other words, heat deposited in the faceplate region 128 may flow to the backplate region 122 by way of the interstitial regions 152. Such heat may then flow up through the vacuum manifold 110, the heating plate assembly 114, the thermal chokes 118, and into the cooling plate assembly 120.

The interstitial regions 152 may have a second total cross-sectional area, which is shown by the cross-hatched pattern in FIG. 5 in a plane nominally parallel (to the faceplate assembly 108, e.g. in a plane parallel to the wafer support surface 164 or the wafer 104, if it is present. The second total cross-sectional area 154 may vary across implementations and may be configured based on gas flow and heat flow considerations. For example, if the faceplate assembly 108 is composed primarily of a material that is more (or less) thermally conductive than the material used to create the depicted faceplate assembly 108, the second total cross- sectional area 154 may be decreased (or increased) to achieve uniform material-independent heat flow between the faceplate region 128 and the backplate region 122. Along the same lines, if more or less heat to flow from the faceplate region 128 to the backplate region 122 is desired, the second total cross-sectional area 154 may be increased or decreased accordingly.

Also or alternatively, if increased gas flow within the network of gas distribution passages 140 is desired, then the second total cross-sectional area 154 may be decreased. Resultantly, the first total cross-sectional area 142 of the gas distribution passages 140 would be increased, increasing the volume of the gas distribution passages 140 and allowing greater gas flow within the plenum region 138.

In one example, when the faceplate assembly 108 is composed primarily of alumina, the present inventors have determined that gas flow and heat transfer considerations recommend that the second total cross-sectional area 154 is between 30% and 40% of the sum of the first total cross-sectional area 142 and the second total cross-sectional area 154.

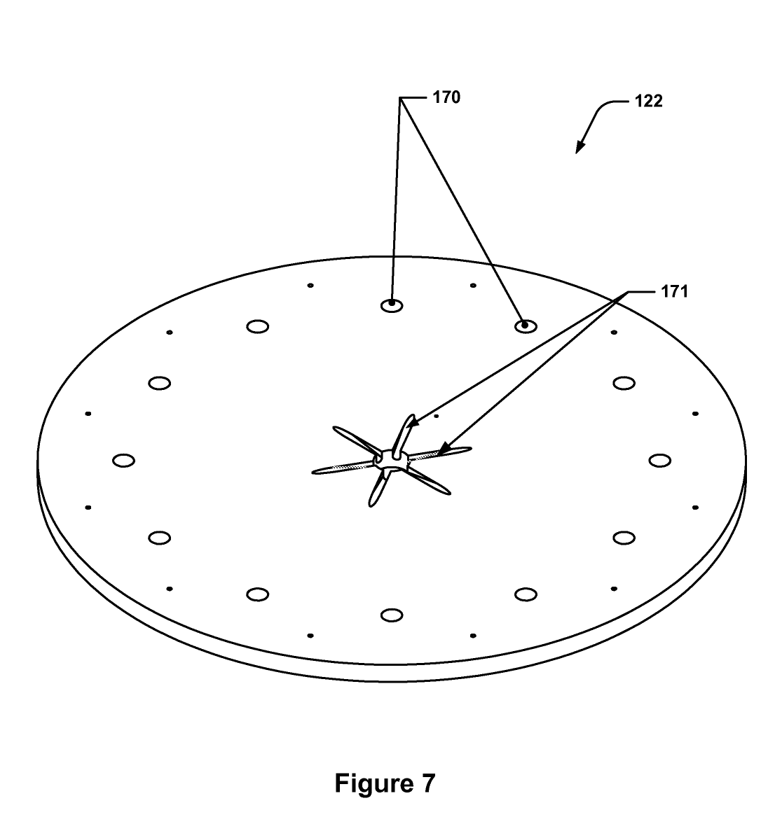

FIG. 7 shows an isometric view of a backplate region 122 of the faceplate assembly 108 of FIG. 3, in accordance with some implementations. As gas flows into the backplate region 122 of the faceplate assembly 108, there may be more pressure near the center of the faceplate assembly 108, since this is where gas may flow into the faceplate assembly 108. As such, in order to allow such gas to radiate outwards effectively into the faceplate assembly 108, the backplate region 122 may include grooves 171. Each groove 171 may correspond to a radial passage 146. Additionally, each groove may decrease in depth with increasing distance from the center of the backplate region 122. As a result, the grooves 171 may increase the volume in which gas may flow, off-setting the higher pressure discussed above.

As shown in FIG. 7, the faceplate assembly 108 may include exhaust ports 170. The exhaust ports 170 may be in fluidic communication with the vacuum manifold 110 such that the vacuum manifold 110 may provide uniform pumping of gas from the microvolume 162 through the faceplate assembly 108, as described further below.

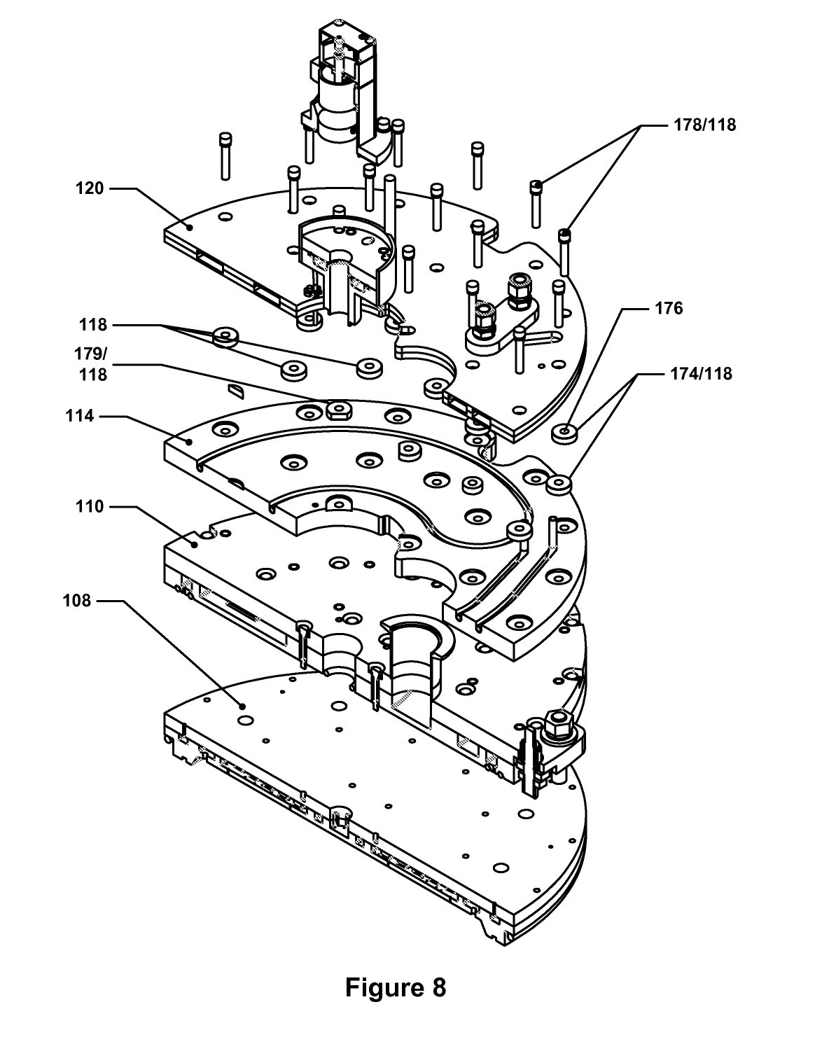

FIG. 8 shows an exploded isometric section view of the gas distribution manifold 106 of FIG. 2, in accordance with some implementations. FIG. 8 separately illustrates some components and features of the gas distribution manifold 106, such as the thermal chokes 118, which can be seen in FIG. 8 between the cooling plate assembly 120 and the heating plate assembly 114.

The thermal chokes 118 may provide a configurable thermally conductive pathway between the cooling plate assembly 120 and the heating plate assembly 114. As a result, the thermal chokes 118 may play a role in transferring heat upwards along the gas distribution manifold 106 from the wafer support pedestal 102 of FIG. 1 and the microvolume 162 of FIG. 3, which may, in some semiconductor processes, be quite hot (approximately 600 degrees Celsius). Such heat may flow from the wafer support pedestal 102 and the microvolume 162 to the faceplate assembly 108, then to the vacuum manifold 110, then to the heating plate assembly 114, across the thermal chokes 118, and then into to the cooling plate assembly 120.

In some implementations, the thermal chokes 118 may be configured to dissipate a designated amount of heat required for semiconductor manufacturing operations performed by the gas distribution manifold 106. For example, during some semiconductor processing operations in the microvolume, significant amounts of heat may be generated, e.g., from chemical reactions in the microvolume or from heat received from a heater in the wafer support, which may be used to heat the wafer. In some implementations, the wafer support that supports the wafer may be heated as high as 600 C. This heat may then flow into the faceplate assembly 108, e.g., via convection, radiation, or conduction through gas in the seal zone 168 of FIG. 3. This heat may then up through the remaining layers of the gas distribution manifold 106, e.g., through the vacuum manifold 110, the heating plate assembly 114, the thermal chokes 118, and then the cooling plate assembly 120. There may be a maximum amount of heat that may need to be removed from the faceplate assembly 108 in order to maintain the faceplate assembly 108 at a steady-state temperature, e.g., in the 200 C to 300 C range, for process stability. To that end, the heat flow from the faceplate assembly 108 may be limited by the thermal chokes to achieve a theoretical maximum amount of heat dissipation needed from the faceplate (absent the thermal chokes, the faceplate might lose heat too quickly, resulting in cooling of the wafer during processing, which may be undesirable).

The thermal chokes 118 may be reconfigured to accommodate a variety of process conditions at low cost and with minimal manpower. By way of illustration, the pedestal 102 may be changed such that there is a decreased total heat transfer to the gas distribution manifold 106 from the pedestal 102. Accordingly, the thermal chokes 118 may be replaced by other thermal chokes having a lower thermal conductivity (e.g. having a smaller diameter than the thermal chokes 118) in order to maintain appropriate heat flow; this may be done without having to re-manufacture or re-design any other components in the assembly, saving significant time and cost.

If, in any instance, less heat removal is desired, the heating plate assembly 114, described in further detail below, may be used to add heat to the gas distribution manifold 106, providing a closed loop temperature control. By way of example, if the maximum heat dissipation required for any contemplated use of a given gas distribution manifold 106 is 3,000 Watts, the thermal chokes 118 may be configured to dissipate 3,000 Watts at steady state conditions consistent with parameters established for the semiconductor operations that are to be performed when such heat is used. If some aspects of the semiconductor manufacturing operations only require 2,500 Watts of heat dissipation, however, 500 additional watts of heating may be provided by the heating plate assembly 114, described in further detail below in order to maintain steady state. The thermal chokes 118 may be the sole thermally conductive pathways between the cooling plate assembly 120 and the heating plate assembly 114, with the exception, for example, of various incidental conductive pathways such as cabling that may allow for some negligible, e.g., less than 5%, in aggregate, of the overall heat transfer between the cooling plate assembly 120 and the heating plate assembly 114, amount of conductive heat transfer between the cooling plate assembly 120 and the heating plate assembly 114. For example, as shown in FIG. 2, the thermal chokes 118 may be located within the gap 116 between the cooling plate assembly 120 and the heating plate assembly 114, preventing other thermally conductive contact between the cooling plate assembly 120 and the heating plate assembly 114. Similarly, as shown in FIG. 2, there may be a gap 115 between the ceramic inlet 156 and both the cooling plate assembly 120 and the heating plate assembly 114, preventing other thermally conductive contact between the cooling plate assembly 120 and the heating plate assembly 114 by way of the ceramic inlet 156. As such, heat may flow predominantly through thermal chokes 118 rather than flowing through other components of the gas distribution manifold 106.

As shown in FIG. 8, each of the thermal chokes 118 may include a spacer 174. Each spacer may include a center region 176, and each thermal choke 118 may include a bolt 178 that passes through the center region 176. The thermal chokes 118 may be composed of a variety of materials based on the amount of thermal conductivity that is desired. For example, in order of decreasing thermal conductivity, the thermal chokes 118 may be composed of copper, aluminum, steel, or titanium. The thermal chokes 118 may vary in size across implementations depending on how much heat dissipation is desired. However, thermal chokes 118 may have a total cross-sectional area (including the spacer 174 and the bolt 178) in a plane parallel to the second exterior surface of FIG. 3 that is between 1.7% and 8.0% of the surface area of the first exterior surface 126, e.g., 1.7% to 8% of the surface area of the faceplate assembly facing towards the thermal chokes and which is in conductive contact with the temperature control assembly or the vacuum manifold assembly.

The spacers 174 may vary in shape across implementations. For example, as shown in FIG. 8, the spacers 174 may be annular in a plane parallel to the second exterior surface 132. Alternatively, spacers 174 may have a different circular or polygonal cross-sectional shape in a plane parallel to the second exterior surface 132. By way of example, a spacer may have an octagonal or hexagonal shape. Generally, the thermal chokes 118 may have the same shape and size and may, therefore, be interchangeable. As shown in FIG. 8, some of thermal chokes 118, such as a thermal choke 179, may vary slightly in size to accommodate various other features in the showerhead, such as the inlet.

The thermal chokes 118 may be arranged in a variety of patterns. For example, as shown in FIG. 8, the thermal chokes 118 may be arranged in one or more circular patterns and may be evenly spaced within each of the circular patterns. Alternatively, such patterns may vary depending on the shape of the gas distribution manifold in which such thermal chokes are included. Alternatively, some or all of the thermal chokes 118 may be arranged in a non-circular pattern.

The spacers 174 may be integral with the heating plate assembly 114 or the cooling plate 120 so as to choke heat flow between the heating plate assembly 114 and the cooling plate assembly 120, as described above. In the depicted implementation, however, the spacers 174 are separate parts, which allows them to be easily replaced with different length spacers 174 or spacers 174 of different cross-sectional areas in order to more easily tune the heat flow characteristics of the thermal chokes 118.

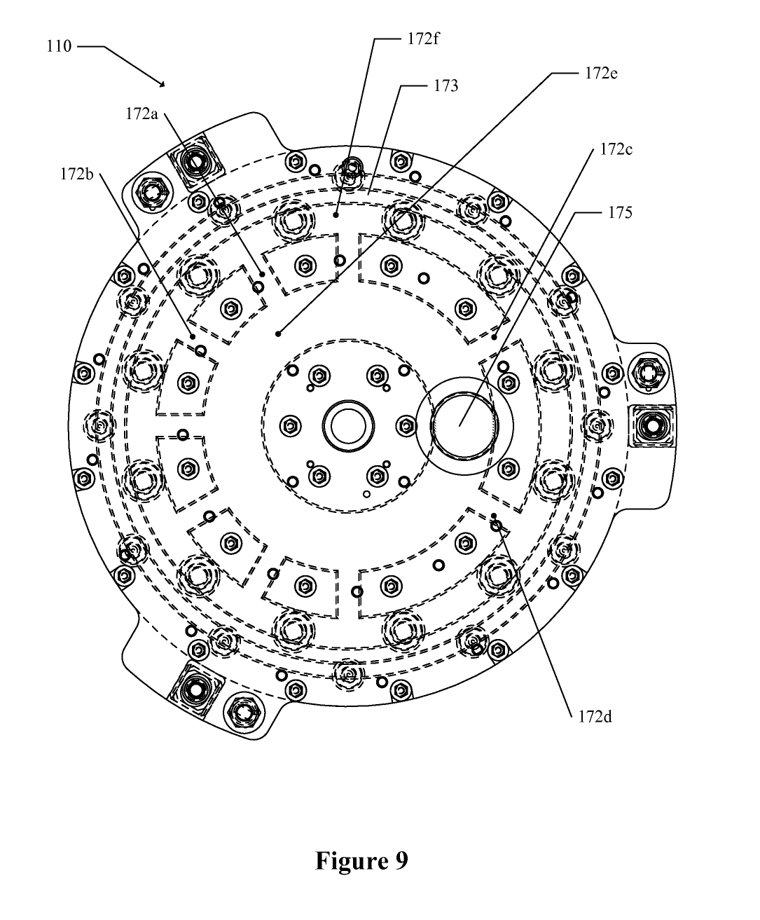

As discussed above, the gas distribution manifold 106 also may include a vacuum manifold 110. For example, FIG. 9 shows a top view of an example of the vacuum manifold 110 of the gas distribution manifold 106 of FIG. 2, in accordance with some implementations. The vacuum manifold 110 may be a Ni-plated, brazed aluminum manifold assembly that may allow the ceramic inlet assembly 156of FIG. 2 and the cleaning gas inlet valve 119 to be sealed to the faceplate assembly 108, although the manifold may also be made from other materials in other implementations and/or coated with other materials (or be uncoated).

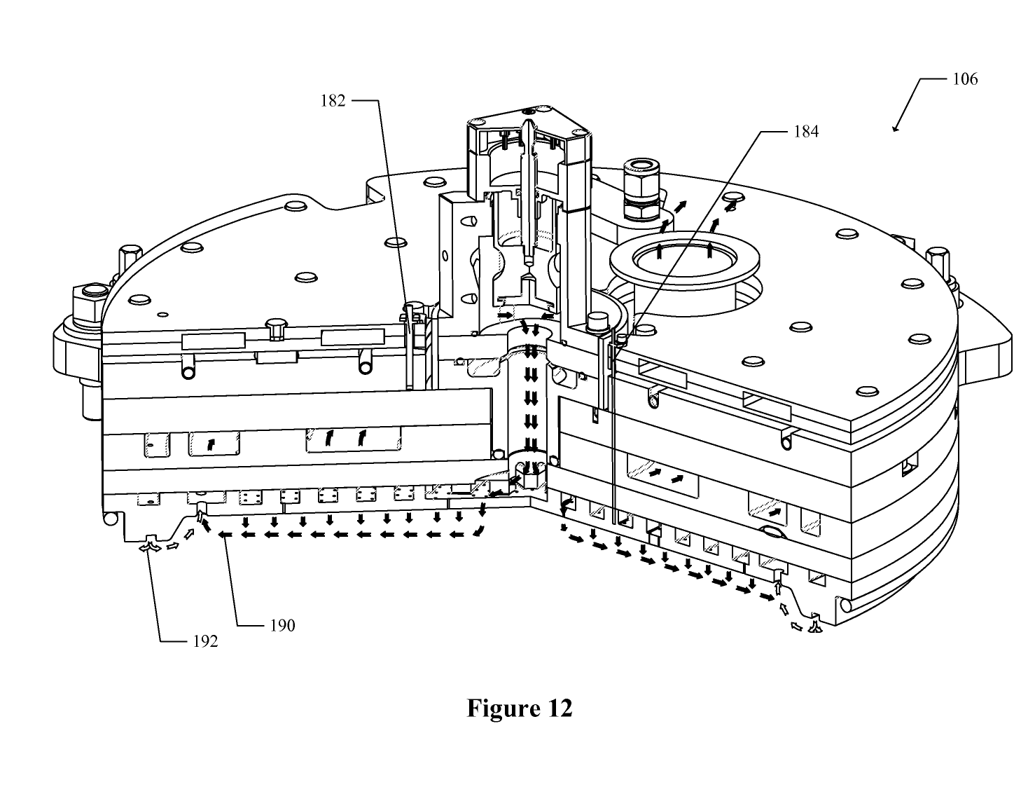

In some implementations, the vacuum manifold 110 of FIG. 9 may remove process gases from the microvolume 162 of FIG. 3. For example, the vacuum manifold 110 may include flow passages 172 to provide uniform pumping of exhaust from the gas distribution manifold 106 and the microvolume 162 by way of the exhaust ports 170 of FIG. 7, as discussed above. Such pumping may draw process gases from the periphery of the wafer 104 of FIG. 3. As a result, process gases may flow across the top surface of the wafer 104 towards the edges of the microvolume 162, as discussed below in the context of FIG. 12.

As shown in FIG. 9, flow passages 172 may be asymmetric. For example, the flow passages 172 may be asymmetrically spaced in that there may be fewer flow passages 172 on the same side of the vacuum manifold as a pumping port 175 than the side opposite the pumping port 175. In other words, flow passages 172a and 172b may be closer together than flow passages 172c and 172d. Along the same lines, the flow passages 172 may vary in size depending on their location within the vacuum manifold 110. For instance, flow passage 172e may be wider than flow passage 172f. Such a placement of the flow passages 172 with respect to the pumping port 175 may provide an even pressure distribution, which may allow uniformity in the pumping described in the preceding paragraph.

In some implementations, the vacuum manifold 110 may contain passages 173 to deliver a barrier gas from a barrier gas source to the seal zone 168 of FIG. 3 by way of the outer passage 166 and the riser passages 167, as discussed above. In some implementations, such features may be part of the pedestal instead of the gas distribution manifold 106.

The location of the vacuum manifold 110 may vary across implementations. For instance as shown in FIGS. 2 and 8, the vacuum manifold 110 may be located within gas distribution manifold 106. Alternatively, the features provided by the vacuum manifold 110 may be incorporated within the wafer support pedestal 102 of FIG. 1.

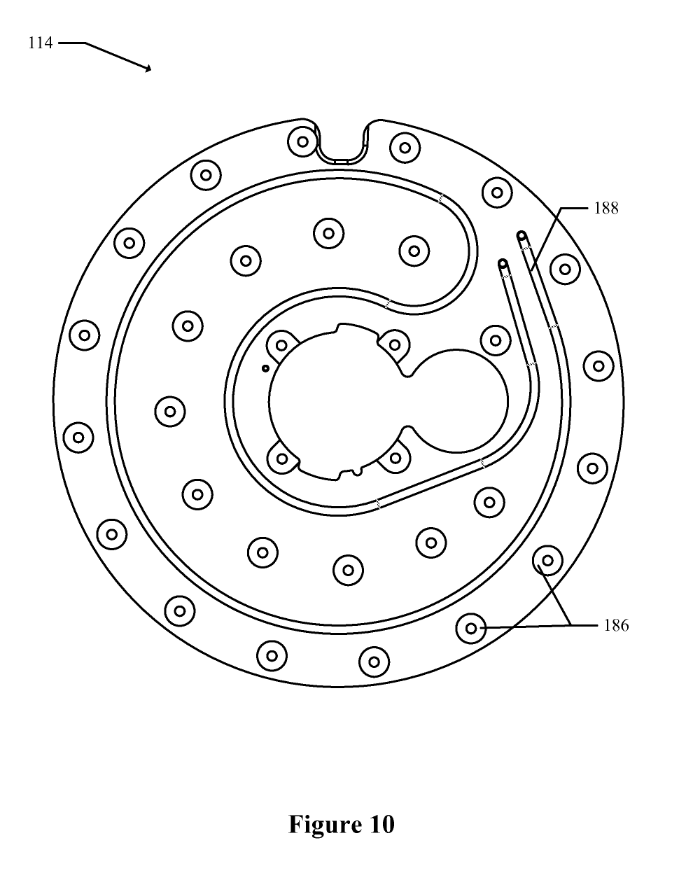

As discussed above, the gas distribution manifold 106 of FIG. 2 may include heating plate assembly 114. FIG. 10 shows a top view of an example of the heating plate assembly 114 of the gas distribution manifold 106 of FIG. 2, in accordance with some implementations. The heating plate assembly 114 may include, for example, a heating plate such as a standard aluminum plate which may conduct heat. Heat may be provided to the plate by a resistive heating element 188 that is either embedded within or placed in close thermal contact with the plate, such as by being pressed into a meandering groove that has been machined into the plate, as shown. For instance, the resistive heating element 188 may have a metallic outer sheath with an internal insulator (such as magnesium oxide) separating a resistive component, such as a coil of nichrome wire, from the sheath. The heat provided to the heating plate assembly 114 may be varied by supplying a varying electrical current through the resistive heating element 188.

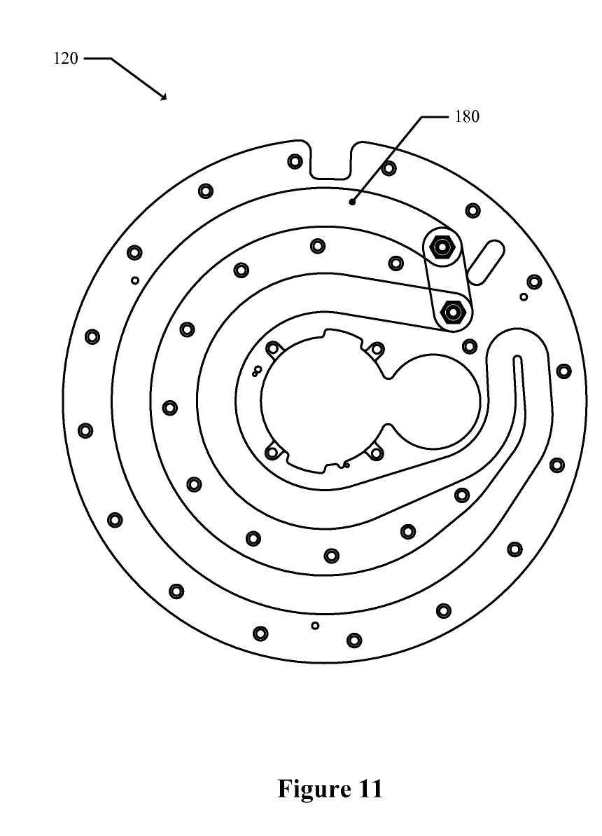

As discussed above, the gas distribution manifold 106 of FIG. 2 may include the cooling plate assembly 120. FIG. 11 shows a top view of an example of the cooling plate assembly 120 of the gas distribution manifold 106 of FIG. 2, in accordance with some implementations. The cooling plate assembly 120 may include cooling passages 180. A cooling liquid such as water may be flowed through the cooling passages 180 to providing thermal control to the faceplate assembly 108. By way of example, cooling water having a temperature in ranging from 15 to 30 degrees Celsius may be flowed through the cooling passages 180 to maintain a temperature of the faceplate assembly 108 in the range of 200 to 300 degrees Celsius. Alternatively, such cooling may be accomplished using a high-temperature-compatible heat transfer fluid such as Galden®.

In some implementations, the gas distribution manifold 106 of FIG. 2 may include a thermocouple (or thermocouples) for temperature measurements of various regions of the gas distribution manifold 106. For example, FIG. 12 shows an isometric cut-away view of the gas distribution manifold 106 in order to illustrate thermocouples 182 and 184, in accordance with some implementations.

In some implementations, the gas distribution manifold 106 may include the thermocouple 182 in the heating plate assembly 114. The thermocouple 182 may provide over-temperature information for the heating plate assembly 114. Also or alternatively, the thermocouple 182 may provide a measurement of the temperature of the bulk of the gas distribution manifold 106.

As shown in FIG. 12, the gas distribution manifold 106 may also include a thermocouple 184 that is inserted through the cooling plate assembly 120, the heating plate assembly 114, the vacuum manifold 110, and into the faceplate assembly 108. The thermocouple 184 may be located in an area of the faceplate assembly 108 occupied by an interstitial region 152 of FIG. 5. Mounting the thermocouple 184 into the faceplate assembly 108 may allow the thermocouple 184 to sense the temperature of the faceplate assembly 108 rather than the temperature of the bulk of the gas distribution manifold 106.

In some implementations, the onset of deposition may be determined based on temperature measurements from the thermocouple 184 at the faceplate assembly 108. For example, thermal emissivity of the wafer 104 of FIG. 1 may change at the onset of deposition, which may result in a distinctive change in temperature in the faceplate assembly 108. As a result, the onset of deposition may be marked by a change in temperature measured by the thermocouple 184 at the faceplate assembly 108.

FIG. 12 also depicts several examples of potential gas flow patterns. For example, white arrows 192 show a potential flow pattern of barrier gas as discussed in the context of FIGS. 3 and 11. Black arrows 190 show a potential flow pattern of process gases as discussed in the context of FIGS. 3 and 11.

In some implementations, the gas distribution manifold may be part of a semiconductor processing tool that includes a controller. Such a controller may be configured to control a wide variety of components of the gas distribution manifold 106; several non-limiting examples are described below. For instance, the controller may be configured to start, stop, increase, or decrease gas flow through the gas distribution manifold 106 by controlling various valves. The controller may be configured to change the amount of electric current running through the resistive heating element 188 of FIG. 10 in order to modulate heat. The controller also may be configured to open or close the cleaning gas inlet valve 119 of FIG. 2.

The controller may be configured to register the start of a deposition cycle when a temperature change is measured by the thermocouple 184 of FIG. 12, as discussed above.

The controller may be part of various systems, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the operations disclosed herein, including the delivery of processing gases, temperature settings (e.g., heating and/or cooling), flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and/or the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The various hardware and method embodiments described above may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility.

Lithographic patterning of a film typically comprises some or all of the following steps, each step enabled with a number of possible tools: (1) application of photoresist on a workpiece, e.g., a substrate having a silicon nitride film formed thereon, using a spin-on or spray-on tool; (2) curing of photoresist using a hot plate or furnace or other suitable curing tool; (3) exposing the photoresist to visible or UV or x-ray light with a tool such as a wafer stepper; (4) developing the resist so as to selectively remove resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above described processes may be changed.

The subject matter of the present disclosure includes all novel and nonobvious combinations and sub-combinations of the various processes, systems and configurations, and other features, functions, acts, and/or properties disclosed herein, as well as any and all equivalents thereof.

What is claimed is:

1. An apparatus for semiconductor manufacturing, the apparatus comprising:
a gas distribution manifold including:
a faceplate assembly having:
a backplate region at least partially bounded by a first interior surface and a first exterior surface,
a faceplate region opposite the backplate region, the faceplate region at least partially bounded by a second interior surface and a second exterior surface, and
a first pattern of gas distribution holes, wherein the gas distribution holes are distributed across the second interior surface and each gas distribution hole spans between the second exterior surface and the second interior surface; and
a temperature control assembly in thermally conductive contact with the second exterior surface, the temperature control assembly having:
a cooling plate assembly having one or more cooling passages configured to be connected with a cooling source,
a heating plate assembly offset from the cooling plate assembly to form a gap, and
a plurality of thermal chokes distributed within the gap, the thermal chokes configured to thermally choke heat flow between the heating plate assembly and the cooling plate assembly.

2. The apparatus of claim 1, wherein the thermal chokes have a total cross-sectional area in a plane parallel to the second exterior surface that is between 1.7% and 8.0% of a surface area of the first exterior surface.

3. The apparatus of claim 1, wherein the thermal chokes include a spacer having a polygonal or circular cross-sectional shape in a plane parallel to the second exterior surface.

4. The apparatus of claim 3, wherein the spacers are integral with the heating plate or the cooling plate.

5. The apparatus of claim 3, wherein the thermal chokes are arranged in one or more circular patterns and are evenly spaced within each of the one or more circular patterns.

6. The apparatus of claim 3, wherein the spacers are annular in the plane parallel to the second exterior surface.

7. The apparatus of claim 6, wherein:
each spacer includes a center region, and
each thermal choke includes a bolt that passes through the center region.

8. The apparatus of claim 1, wherein the faceplate assembly is composed primarily of a ceramic material.

9. The apparatus of claim 8, wherein:
the faceplate assembly further includes a ceramic inlet, and
process gases flowed into the gas distribution manifold via the ceramic inlet are exposed primarily to the ceramic material of which the faceplate assembly is composed when within the gas distribution manifold.

10. The apparatus of claim 1, wherein the faceplate assembly further includes:
a plenum region at least partially bounded by the first and second interior surfaces, the plenum region comprising:
a network of gas distribution passages for distributing gas, the gas distribution passages having a first total cross-sectional area in a plane nominally parallel to the faceplate assembly, and
a plurality of interstitial regions defined by the network of gas distribution passages, the interstitial regions spanning between the first interior surface and the second interior surface, the interstitial regions having a second total cross-sectional area in the plane nominally parallel to the faceplate assembly.

11. The apparatus of claim 10, wherein the interstitial regions are free of gas distribution holes.

12. The apparatus of claim 10, wherein each interstitial region forms a thermally conductive pathway between the faceplate region and the backplate region.

13. The apparatus of claim 10, wherein the gas distribution passages include:
a plurality of radial spoke passages, and
a plurality of concentric annular passages fluidically connected with the plurality of radial spoke passages.

14. The apparatus of claim 13, wherein the radial spoke passages form a circular array about an inlet of the gas distribution manifold and each radial spoke passage has at least a portion where that radial spoke passage decreases in cross-sectional area in a plane perpendicular to the radial spoke passage as a function of increasing distance from the inlet.

15. The apparatus of claim 10, wherein the second cross-sectional area is between 30% and 40% of a sum of the first cross-sectional area and the second cross-sectional area.

16. The apparatus of claim 1, wherein:
the second exterior surface includes a circumferential wall portion that is offset in a direction away from the second interior surface from a center portion of the second exterior surface enclosed within the circumferential wall portion, and
the circumferential wall portion is configured to interface with a wafer support pedestal located in a semiconductor processing chamber when the gas distribution manifold is installed in the semiconductor processing chamber so as to define a microvolume bounded, at least in part, by the center portion, the circumferential wall portion, and a wafer support surface of the wafer support pedestal when the apparatus is used to perform one or more semiconductor processing operations on a wafer, wherein the apparatus further comprises a vacuum manifold configured to remove process gases from the microvolume.

17. The apparatus of claim 16, further comprising an outer passage, wherein:
the outer passage is configured to provide a barrier gas to a seal zone between the second exterior surface and the wafer support pedestal, and
the seal zone is a region where the second exterior surface and the wafer support pedestal are closest when the microvolume exists.

18. The apparatus of claim 16, wherein the vacuum manifold is located between the heating plate assembly and the faceplate assembly.

19. The apparatus of claim 18, wherein the faceplate assembly includes exhaust ports in fluidic communication with the vacuum manifold.

20. The apparatus of claim 19, wherein the vacuum manifold includes flow passages configured to provide asymmetric flow paths to gases flowing within the vacuum manifold.

21. The apparatus of claim 1, wherein the faceplate assembly includes a thermocouple configured to measure a temperature of the faceplate region.
